(19) United States
(12) Patent Application Publication
(10) Pub. No.: US 2024/0332374 A1
(43) Pub. Date: Oct. 3, 2024

(54) Contact Formation Method and Related Structure

(71) Applicant: Taiwan Semiconductor Manufacturing Company, Ltd., Hsinchu (TW)

(72) Inventors: Chi-Cheng HUNG, Tainan City (TW); Pei-Wen WU, Hsinchu County (TW); Pei Shan CHANG, Hsinchu City (TW)

(21) Appl. No.: 18/492,382

(22) Filed: Oct. 23, 2023

Related U.S. Application Data
(60) Provisional application No. 63/492,336, filed on Mar. 27, 2023.

(51) Int. Cl. H01L 29/40; H01L 21/768; H01L 23/522; H01L 23/532; H01L 29/417; H01L 29/45

(52) U.S. Cl. CPC H01L 29/401; H01L 21/76883; H01L 23/5226; H01L 23/53257; H01L 29/41725; H01L 29/456; H01L 21/76843

(57) ABSTRACT

A method and structure for forming semiconductor device includes forming a first opening in a dielectric layer to expose a source/drain region. In some embodiments, the method further includes depositing a first metal layer in the opening and over the source/drain region. Thereafter, in some examples, the method further includes performing an annealing process to modulate a grain size of the first metal layer. In various embodiments, the method further includes depositing a second metal layer over the annealed first metal layer. In some embodiments, the second metal layer has a substantially uniform phase.

### CROSS-REFERENCE TO RELATED APPLICATION

This application claims the benefit of U.S. Provisional Application No. 63/492,336, filed Mar. 27, 2023, the entirety of which is incorporated by reference herein.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

As merely one example, forming a reliable contact to a source, drain, and/or body region requires reliable and low resistance contact plugs and contact vias. For at least some conventional processes, the resistance of such contact and via structures remains a device performance and reliability issue, especially with the continued scaling of IC dimensions. In some cases, non-optimized processes may cause contact plugs and/or contact vias to suffer from increased resistance due to a non-uniform film phase of constituent materials. Further in some examples, such non-optimized processes may also cause via-to-via variation and various other defects.

Thus, existing techniques have not proved entirely satisfactory in all respects.

### BRIEF DESCRIPTION OF THE DRAWINGS

Aspects of the present disclosure are best understood from the following detailed description when they are read with the accompanying figures. It is noted that, in accordance with the standard practice in the industry, various features are not drawn to scale. In fact, the dimensions of the various features may be arbitrarily increased or reduced for clarity of discussion.

FIG. 1A is a cross-sectional view of an MOS transistor according to some embodiments;

FIG. 1B is perspective view of an embodiment of a FinFET device according to one or more aspects of the present disclosure;

FIG. 2 is a flow chart of a method of forming contact structures and including contact plugs and contact vias, according to some embodiments;

FIGS. 3, 4, 5, 6, 7, 8, 9, and 10 provide cross-sectional views of a device at intermediate stages of fabrication and processed in accordance with the method of FIG. 2, along a plane substantially parallel to a plane defined by section AA′ of FIG. 1B, according to some embodiments; and

FIG. 11 provides a cross-sectional view of an alternative device fabricated substantially in accordance with the method of FIG. 2, along a plane substantially parallel to a plane defined by section AA′ of FIG. 1B, according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

It is also noted that the present disclosure presents embodiments in the form of contact plugs and/or contact vias which may be employed in any of a variety of device types. For example, embodiments of the present disclosure may be used to form contact plugs and/or contact vias in planar bulk metal-oxide-semiconductor field-effect transistors (MOSFETs), multi-gate transistors (planar or vertical) such as FinFET devices, gate-all-around (GAA) devices, Omega-gate (Ω-gate) devices, or Pi-gate (Π-gate) devices, as well as strained-semiconductor devices, silicon-on-insulator (SOI) devices, partially-depleted SOI (PD-SOI) devices, fully-depleted SOI (FD-SOI) devices, or other devices as known in the art. In addition, embodiments disclosed herein may be employed in the formation of P-type and/or N-type devices. One of ordinary skill may recognize other embodiments of semiconductor devices that may benefit from aspects of the present disclosure.

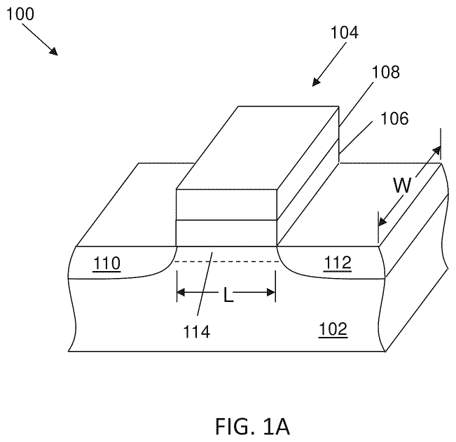

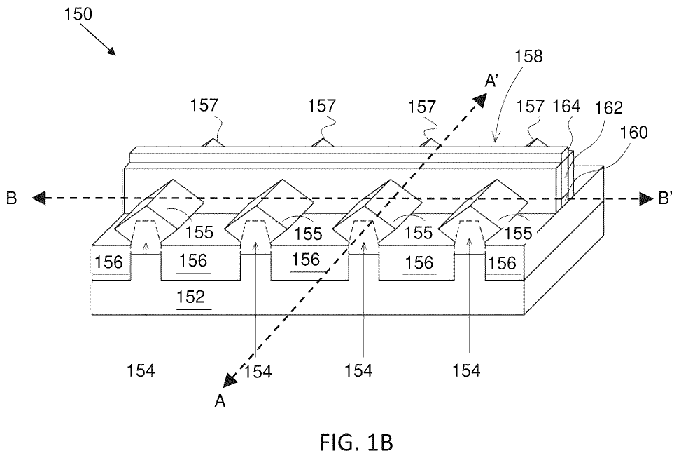

With reference to the example of FIG. 1A, illustrated therein is an MOS transistor 100, providing an example of merely one device type which may include embodiments of the present disclosure. It is understood that the exemplary transistor 100 is not meant to be limiting in any way, and those of skill in the art will recognize that embodiments of the present disclosure may be equally applicable to any of a variety of other device types, such as those described above. The transistor 100 is fabricated on a substrate 102 and includes a gate stack 104. The substrate 102 may be a semiconductor substrate such as a silicon substrate. The substrate 102 may include various layers, including conductive or insulating layers formed on the substrate 102. The substrate 102 may include various doping configurations depending on design requirements as is known in the art. The substrate 102 may also include other semiconductors such as germanium, silicon carbide (SiC), silicon germanium (SiGe), or diamond. Alternatively, the substrate 102 may include a compound semiconductor and/or an alloy semiconductor. Further, in some embodiments, the substrate 102 may include an epitaxial layer (epi-layer), the substrate 102 may be strained for performance enhancement, the substrate 102 may include a silicon-on-insulator (SOI) structure, and/or the substrate 102 may have other suitable enhancement features.

The gate stack 104 includes a gate dielectric 106 and a gate electrode 108 disposed on the gate dielectric 106. In some embodiments, the gate dielectric 106 may include an interfacial layer such as silicon oxide layer (SiO₂) or silicon oxynitride (SiON), where such interfacial layer may be formed by chemical oxidation, thermal oxidation, atomic layer deposition (ALD), chemical vapor deposition (CVD), and/or other suitable method. In some examples, the gate dielectric 106 includes a high-K dielectric layer such as hafnium oxide (HfO₂). Alternatively, the high-K dielectric layer may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable material. High-K gate dielectrics, as used and described herein, include dielectric materials having a high dielectric constant, for example, greater than that of thermal silicon oxide (˜3.9). In still other embodiments, the gate dielectric 106 may include silicon dioxide or other suitable dielectric. The gate dielectric 106 may be formed by ALD, physical vapor deposition (PVD), CVD, oxidation, and/or other suitable methods. In some embodiments, the gate electrode 108 may be deposited as part of a gate first or gate last (e.g., replacement gate) process. In various embodiments, the gate electrode 108 includes a conductive layer such as W, Ti, TiN, TiAl, TiAlN, Ta, TaN, WN, Re, Ir, Ru, Mo, Al, Cu, Co, CoSi, Ni, NiSi, combinations thereof, and/or other suitable compositions. In some examples, the gate electrode 108 may include a first metal material for an N-type transistor and a second metal material for a P-type transistor. Thus, the transistor 100 may include a dual work-function metal gate configuration. For example, the first metal material (e.g., for N-type devices) may include metals having a work function substantially aligned with a work function of the substrate conduction band, or at least substantially aligned with a work function of the conduction band of a channel region 114 of the transistor 100. Similarly, the second metal material (e.g., for P-type devices) may include metals having a work function substantially aligned with a work function of the substrate valence band, or at least substantially aligned with a work function of the valence band of the channel region 114 of the transistor 100. Thus, the gate electrode 104 may provide a gate electrode for the transistor 100, including both N-type and P-type devices. In some embodiments, the gate electrode 108 may alternately or additionally include a polysilicon layer. In various examples, the gate electrode 108 may be formed using PVD, CVD, electron beam (e-beam) evaporation, and/or other suitable process. In some embodiments, sidewall spacers are formed on sidewalls of the gate stack 104. Such sidewall spacers may include a dielectric material such as silicon oxide, silicon nitride, silicon carbide, silicon oxynitride, or combinations thereof.

The transistor 100 further includes a source region 110 and a drain region 112 each formed within the semiconductor substrate 102, adjacent to and on either side of the gate stack 104. In some embodiments, the source and drain regions 110, 112 include diffused source/drain regions, ion implanted source/drain regions, epitaxially grown source/drain regions, or a combination thereof. The channel region 114 of the transistor 100 is defined as the region between the source and drain regions 110, 112 under the gate dielectric 106, and within the semiconductor substrate 102. The channel region 114 has an associated channel length “L” and an associated channel width “W”. When a bias voltage greater than a threshold voltage (Vt) (i.e., turn-on voltage) for the transistor 100 is applied to the gate electrode 108 along with a concurrently applied bias voltage between the source and drain regions 110, 112, an electric current (e.g., a transistor drive current) flows between the source and drain regions 110, 112 through the channel region 114. The amount of drive current developed for a given bias voltage (e.g., applied to the gate electrode 108 or between the source and drain regions 110, 112) is a function of, among others, the mobility of the material used to form the channel region 114. In some examples, the channel region 114 includes silicon (Si) and/or a high-mobility material such as germanium, which may be epitaxially grown, as well as any of the plurality of compound semiconductors or alloy semiconductors as known in the art. High-mobility materials include those materials with electron and/or hole mobility greater than silicon (Si), which has an intrinsic electron mobility at room temperature (300 K) of around 1350 cm²/V-s and an intrinsic hole mobility at room temperature (300 K) of around 480 cm²/V-s.

Referring to FIG. 1B, illustrated therein is a FinFET device 150, providing an example of an alternative device type which may include embodiments of the present disclosure. By way of example, the FinFET device 150 includes one or more fin-based, multi-gate field-effect transistors (FETs). The FinFET device 150 includes a substrate 152, at least one fin element 154 extending from the substrate 152, isolation regions 156, and a gate structure 158 disposed on and around the fin element 154. The substrate 152 may be a semiconductor substrate such as a silicon substrate. In various embodiments, the substrate 152 may be substantially the same as the substrate 102 and may include one or more of the materials used for the substrate 102, as described above.

The fin element 154, like the substrate 152, may include one or more epitaxially-grown layers, and may comprise silicon or another elementary semiconductor, such as germanium; a compound semiconductor including silicon carbide, gallium arsenide, gallium phosphide, indium phosphide, indium arsenide, and/or indium antimonide; an alloy semiconductor including SiGe, GaAsP, AlInAs, AlGaAs, InGaAs, GaInP, and/or GaInAsP; or combinations thereof. The fin elements 154 may be fabricated using suitable processes including photolithography and etch processes. The photolithography process may include forming a photoresist layer (resist) overlying the substrate (e.g., on a silicon layer), exposing the resist to a pattern, performing post-exposure bake processes, and developing the resist to form a masking element including the resist. In some embodiments, pattering the resist to form the masking element may be performed using an electron beam (e-beam) lithography process. The masking element may then be used to protect regions of the substrate while an etch process forms recesses into the silicon layer, thereby leaving the extending fin elements 154. The recesses may be etched using a dry etch (e.g., chemical oxide removal), a wet etch, and/or other suitable processes. Numerous other embodiments of methods to form the fin elements 154 on the substrate 152 may also be used.

Each of the plurality of fin elements 154 also include a source region 155 and a drain region 157 where the source/drain regions 155, 157 are formed in, on, and/or surrounding the fin element 154. The source/drain regions 155, 157 may be epitaxially grown over the fin elements 154. In addition, a channel region of a transistor is disposed within the fin element 154, underlying the gate structure 158, along a plane substantially parallel to a plane defined by section AA′ of FIG. 1B. In some examples, the channel region of the fin element 154 includes a high-mobility material, as described above.

The isolation regions 156 may be shallow trench isolation (STI) features. Alternatively, a field oxide, a LOCOS feature, and/or other suitable isolation features may be implemented on and/or within the substrate 152. The isolation regions 156 may be composed of silicon oxide, silicon nitride, silicon oxynitride, fluorine-doped silicate glass (FSG), a low-K dielectric, combinations thereof, and/or other suitable material known in the art. In an embodiment, the isolation regions 156 are STI features and are formed by etching trenches in the substrate 152. The trenches may then be filled with isolating material, followed by a chemical mechanical polishing (CMP) process. However, other embodiments are possible. In some embodiments, the isolation regions 156 may include a multi-layer structure, for example, having one or more liner layers.

The gate structure 158 includes a gate stack having an interfacial layer 160 formed over the channel region of the fin 154, a gate dielectric layer 162 formed over the interfacial layer 160, and a metal layer 164 formed over the gate dielectric layer 162. In various embodiments, the interfacial layer 160 is substantially the same as the interfacial layer described as part of the gate dielectric 106. In some embodiments, the gate dielectric layer 162 is substantially the same as the gate dielectric 106 and may include high-K dielectrics similar to that used for the gate dielectric 106. Similarly, in various embodiments, the metal layer 164 is substantially the same as the gate electrode 108, described above. In some embodiments, sidewall spacers are formed on sidewalls of the gate structure 158. The sidewall spacers may include a dielectric material such as silicon oxide, silicon nitride, silicon carbide, silicon oxynitride, or combinations thereof.

As discussed above, each of the transistor 100 and FinFET device 150 may include one or more contact plugs and/or contact vias, embodiments of which are described in more detail below. In some examples, the contact plugs and/or contact vias described herein may be part of a local interconnect structure. As used herein, the term “local interconnect” is used to describe the lowest level of metal interconnects and are differentiated from intermediate and/or global interconnects. Local interconnects span relatively short distances and are sometimes used, for example, to electrically connect a source, drain, body, and/or gate of a given device, or those of nearby devices. Additionally, local interconnects may be used to facilitate a vertical connection of one or more devices to an overlying metallization layer (e.g., to an intermediate interconnect layer), for example, through one or more vias. Interconnects (e.g., including local, intermediate, or global interconnects), in general, may be formed as part of back-end-of-line (BEOL) fabrication processes and include a multi-level network of metal wiring. Moreover, any of a plurality of IC circuits and/or devices (e.g., such as the transistor 100 or FinFET 150) may be connected by such interconnects.

With the aggressive scaling and ever-increasing complexity of advanced IC devices and circuits, contact and local interconnect design has proved to be a difficult challenge. By way of example, forming a reliable contact to a source, drain, and/or body region requires reliable and low resistance contact plugs and contact vias. For at least some conventional processes, the resistance of such contact and via structures remains a device performance and reliability issue, especially with the continued scaling of IC dimensions. In some implementations, a cobalt (Co) contact plug may be used to contact an epitaxial source/drain region, and a tungsten (W) via may formed over and in contact with the contact plug. Due at least in part to non-optimized processes, the contact plugs and/or vias may suffer from increased resistance due to a non-uniform film phase of constituent materials. For instance, in some current implementations, less than 50% of the Co includes a hexagonal close-packed (HCP) crystal structure, and the overlying W (used to form the W via) may form in the beta phase as beta-tungsten (β-W), which has a high resistivity. In some examples, such non-optimized processes may also cause via-to-via variation and various other defects (e.g., such as Ti-insertion or a broken W layer).

More particularly, in some existing implementations, the non-optimized process may cause the cobalt (Co) used for the contact plug to have a non-optimal grain size (e.g., too small or too big). In some cases, if the Co grain size is too small, tungsten (W) growth on the Co contact plug (e.g., to form an overlying via) may be slow and the W may not fully fill a desired via region. This can result in a Ti-insertion defect (e.g., from an overlying metal layer) into the W via region. In other cases, if the Co grain is too large, the tungsten (W) growth on the Co contact plug (e.g., to form the overlying via) may be fast and could potentially cause W overgrowth. This can result in a broken W layer, for instance, caused by stress during a contact via chemical mechanical polishing (CMP) process. It is also noted that as critical dimensions (CDs) shrink with continued aggressive scaling, the Co grain size will become smaller and the formation of beta-tungsten (β-W) vias can happen more easily. Thus, existing methods have not been entirely satisfactory in all respects.

Embodiments of the present disclosure offer advantages over the existing art, though it is understood that other embodiments may offer different advantages, not all advantages are necessarily discussed herein, and no particular advantage is required for all embodiments. For example, embodiments discussed herein include methods and structures directed to a fabrication process for contact structures and including contact plugs and contact vias. Stated another way, the embodiments disclosed herein generally provide for an optimized contact loop process (e.g., which includes formation of contact plugs and overlying contact vias). More particularly, embodiments of the present disclosure provide a method for optimizing the grain size of the Co used to form the contact plug, resulting in contacts and vias that are substantially defect-free, have reduced resistance, and provide improved gap-fill capability. The formation of a contact plug may include, among other steps, formation of an opening in a dielectric layer, deposition of a Co layer within the opening, and an annealing process (e.g., to optimize the grain size of the Co). After the annealing process, a CMP process is performed to finalize formation of the contact plug, and a via (e.g., such as a W via) may then be formed over the contact plug.

In order to optimize the grain size of Co, various embodiments provide for optimizing the annealing process performed after Co deposition to modulate the grain size of the as-deposited Co. In some embodiments, the annealing process is performed at a temperature of about 250-400 degrees Celsius, in a 30-70% H₂ ambient environment (e.g., for improved impurity reduction), at a pressure of about 10-30 Torr, and for a duration of about 5-10 minutes. Annealing in the H₂ ambient environment may in some cases be equivalently referred to as a H₂ soak or H₂ soaking process. In some embodiments, a grain size of the annealed cobalt (and the subsequently formed Co contact plug) is in a range of about 30-90 nm². By providing this optimized Co grain size, the W via growth on the Co contact plug will proceed at an ideal rate (e.g., about 8-12 Angstroms per second) such that via-to-via variation and various other defects (e.g., such as Ti-insertion or a broken W layer) can be substantially avoided and device yield can be improved. Moreover, the optimized Co grain size provides for control of the W phase of the W vias (e.g., providing a substantially uniform film phase of the W vias), resulting in a boost in device performance. For instance, using the disclosed H₂ soak, greater than 50% of the Co may include a hexagonal close-packed (HCP) crystal structure, and the overlying W (used to form the W via) may form in the alpha phase as alpha-tungsten (α-W), which has a lower resistivity than beta-tungsten (β-W). Even with shrinking CDs, embodiments of the present disclosure provide for optimal Co grain size and formation of low resistivity alpha-tungsten (β-W) vias.

As discussed above, the embodiments disclosed herein may also be employed in a variety of device types and/or structures. For example, various embodiments may be employed as part of a contact loop process performed during the fabrication of a planar device (e.g., as shown in FIG. 1A), a FinFET device (e.g., as shown in FIG. 1B), a GAA device, or other suitable device. Further, in some cases, embodiments of the present disclosure may be employed in other situations where a contact/via is formed. As one example, some embodiments may be employed during the formation of a backside contact plug/backside via (e.g., for backside power delivery). Additional details of embodiments of the present disclosure are provided below, and additional benefits and/or other advantages will become apparent to those skilled in the art having benefit of the present disclosure.

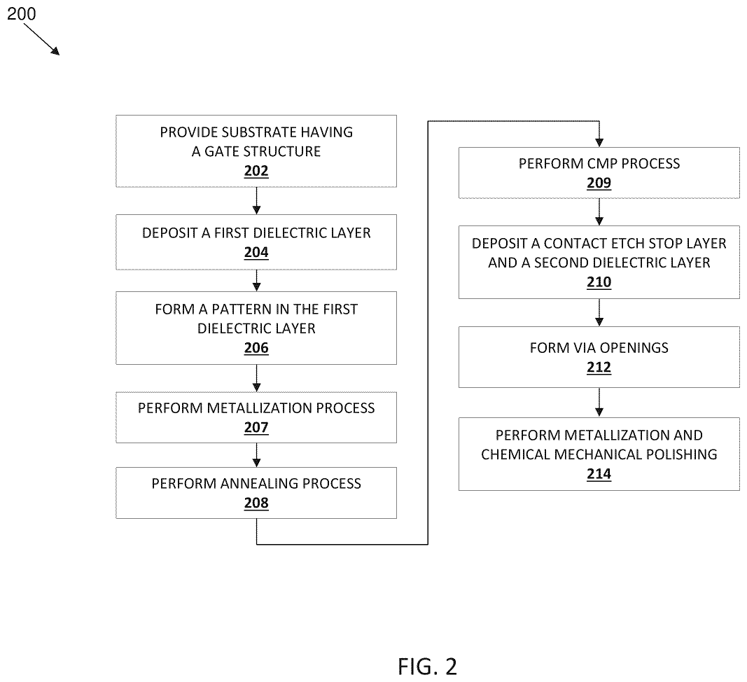

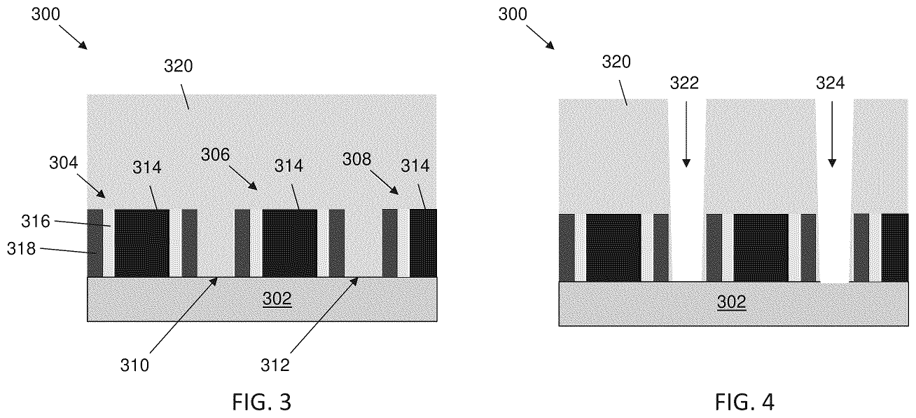

Referring now to FIG. 2, illustrated is a method 200 of forming contact structures and including contact plugs and contact vias, in accordance with some embodiments. The method 200 is described below in more detail with reference to FIGS. 3-10, which provide cross-sectional views of a device 300 along a plane substantially parallel to a plane defined by section AA′ of FIG. 1B. The method 200 may be implemented on a single-gate planar device, such as the exemplary transistor 100 described above with reference to FIG. 1A, as well as on a multi-gate device, such as the FinFET device 150 described above with reference to FIG. 1B. Thus, one or more aspects discussed above with reference to the transistor 100 and/or the FinFET 150 may also apply to the method 200. To be sure, in various embodiments, the method 200 may be implemented on other devices such as GAA devices, Ω-gate devices, or Π-gate devices, as well as strained-semiconductor devices, SOI devices, PD-SOI devices, FD-SOI devices, or in other situations where a contact/via is formed (e.g., such as during the formation of a backside contact plug/backside via for backside power delivery).

It is understood that parts of the method 200 and/or any of the exemplary transistor devices discussed with reference to the method 200 may be fabricated by a well-known complementary metal-oxide-semiconductor (CMOS) technology process flow, and thus some processes are only briefly described herein. Further, it is understood that any exemplary transistor devices discussed herein may include various other devices and features, such as additional transistors, bipolar junction transistors, resistors, capacitors, diodes, fuses, etc., but are simplified for a better understanding of the inventive concepts of the present disclosure. Further, in some embodiments, the exemplary transistor device(s) disclosed herein may include a plurality of semiconductor devices (e.g., transistors), which may be interconnected. In addition, in some embodiments, various aspects of the present disclosure may be applicable to either one of a gate-last process or a gate-first process.

In addition, in some embodiments, the exemplary transistor devices illustrated herein may include a depiction of a device at an intermediate stage of processing, as may be fabricated during processing of an integrated circuit, or portion thereof, that may comprise static random access memory (SRAM) and/or other logic circuits, passive components such as resistors, capacitors, and inductors, and active components such as P-channel field-effect transistors (PFETs), N-channel FETs (NFETs), MOSFETs, CMOS transistors, bipolar transistors, high voltage transistors, high frequency transistors, other memory cells, and/or combinations thereof.

The method 200 begins at block 202 where a substrate having a gate structure is provided. With reference to FIG. 3, and in an embodiment of block 202, a device 300 having a substrate 302 and including gate structures 304, 306, 308 is provided. In some embodiments, the substrate 302 may be substantially the same as either of the substrates 102, 152, described above. A region of the substrate 302 upon which the gate structures 304, 306, 308 are formed, and including regions of the substrate 302 between adjacent gate structures 304, 306, 308, may include an active region of the substrate 302. It will be understood that the device 300 is merely illustrative and is provided for clarity of discussion with respect to the method 200. For example, in some cases, the device 300 may include a planar device, such as the transistor 100. Alternatively, in some examples, the device 300 may include a multi-gate device, such as the FinFET 150. Moreover, in some cases, the device 300 may include a GAA device, an Ω-gate device, a Π-gate device, a strained-semiconductor device, an SOI device, a PD-SOI device, a FD-SOI device, or other device as known in the art. In some embodiments, the device 300 includes regions 310, 312, adjacent to the gate structures 304, 306, 308, where the regions 310, 312 may include a source/drain region or a body contact region. In an example, the regions 310, 312 may both include N-type regions or P-type regions. Alternatively, one of the regions 310, 312 may include an N-type region and the other one of the regions 310, 312 may include a P-type region. In various embodiments, each of the gate structures 304, 306, 308 may include an interfacial layer formed over the substrate 302, a gate dielectric layer formed over the interfacial layer, and a gate electrode layer 314 formed over the gate dielectric layer. In some embodiments, each of the interfacial layer, the dielectric layer, and the gate electrode layer 314 of the gate structures 304, 306, 308 may be substantially the same as those described above with respect to the transistor 100 and the FinFET 150. However, it is also noted that in some cases, the gate electrode layer 314 may include a metal capping layer as a topmost layer, where the metal capping layer includes a tungsten (W) layer. In at least some cases, the gate structures 304, 306, 308 may include dummy gate structures that are replaced at a later stage of processing by a high-K/metal gate structure (e.g., such as in a replacement gate process). In addition, each of the gate structures 304, 306, 308 may include sidewall spacer layers 316, 318. In some cases, each of the sidewall spacer layers 316, 318 include materials having different dielectric constant values (e.g., K values). In various embodiments, the sidewall spacer layers 316, 318 include SiOₓ, SiN, SiOₓN_{y}, SiCₓN_{y}, SiOₓC_{y}N_{z}, AlOₓ, AlOₓN_{y}, AlN, HfO, ZrO, HfZrO, CN, poly-Si, combinations thereof, or other suitable dielectric materials. In some embodiments, the sidewall spacer layers 316, 318 include multiple layers, such as main spacer walls, liner layers, and the like. By way of example, the sidewall spacer layers 316, 318 may be formed by depositing a dielectric material over the device 300 and anisotropically etching back the dielectric material. In some embodiments, the etch-back process (e.g., for spacer formation) may include a multiple-step etching process to improve etch selectivity and provide over-etch control.

The method 200 proceeds to block 204 where a first dielectric layer is deposited over the substrate. Still referring to FIG. 3, and in an embodiment of block 204, a dielectric layer 320 is formed over the substrate 302 and over each of the gate structures 304, 306, 308. By way of example, the dielectric layer 320 may include an inter-layer dielectric (ILD) layer that may include materials such as tetraethylorthosilicate (TEOS) oxide, undoped silicate glass, or doped silicon oxide such as borophosphosilicate glass (BPSG), fluorosilicate glass (FSG), phosphosilicate glass (PSG), boron doped silicon glass (BSG), and/or other suitable dielectric materials. The dielectric layer 320 may be deposited by a subatmospheric CVD (SACVD) process, a flowable CVD process, or other suitable deposition technique.

The method 200 proceeds to block 206 where a pattern is formed in the first dielectric layer. With reference to FIGS. 3 and 4, and in an embodiment of block 206, a pattern, that includes openings 322, 324, is formed within the dielectric layer 320. In some cases, the openings 322, 324 provide access to regions 310, 312, adjacent to the gate structures 304, 306, 308, where the regions 310, 312 may include a source/drain region or a body contact region. By way of example, the openings 322, 324 may be formed by a suitable combination of lithographic patterning and etching (e.g., wet or dry etching) processes. In some cases, the openings 322, 324 may be referred to as metal plug openings, contact plug openings, or plug openings.

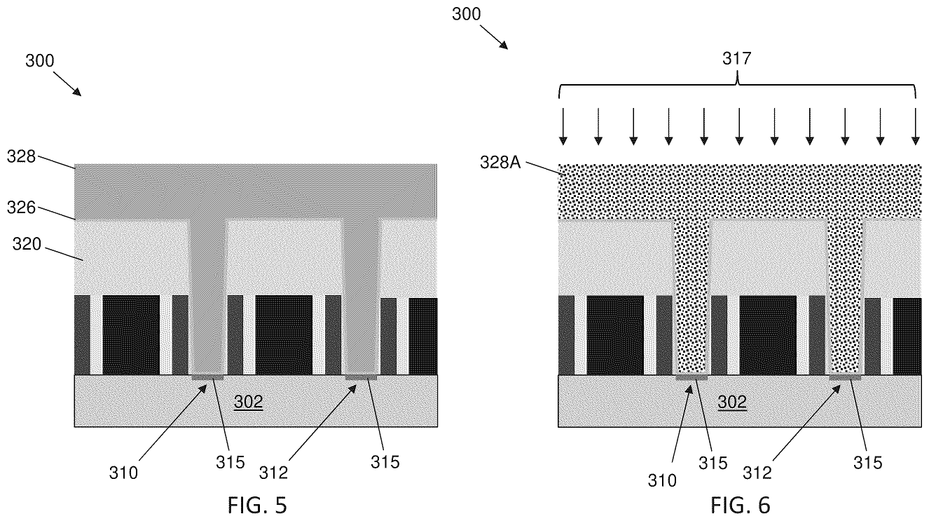

The method 200 proceeds to block 207 where a metallization process is performed. With reference to FIGS. 4 and 5, and in an embodiment of block 207, a silicidation process may initially be performed to form a silicide layer 315 on exposed portions of the substrate 302 (e.g., exposed by the openings 322, 324) in the regions 310, 312, thus providing a low resistance contact thereto. In an embodiment, the silicide layer 315 may include titanium silicide (TiSi). In other embodiments, the silicide layer 315 may include tungsten silicide (WSi), cobalt silicide (CoSi), nickel silicide (NiSi), nickel-platinum silicide (NiPtSi), or other appropriate silicide layer. The silicide layer 315, in some cases, may have a thickness in a range of about 4-8 nm. In some examples, and in a further embodiment of block 207, a glue or barrier layer 326 may be formed over the device 300, including on sidewall surfaces within each of the openings 322, 324, over the silicide layer 315, and over top surfaces of the dielectric layer 320. In some cases, the glue or barrier layer 326 may include Ti, TiN, Ta, TaN, a combination thereof, or other appropriate material. In at least some examples, the glue or barrier layer 326 includes a Ti/TiN stack. The glue or barrier layer 326, in some cases, may have a thickness in a range of about 0.5-1.5 nm. In some cases, and prior to deposition of the glue or barrier layer 326, another barrier layer including SiN, TiSiN, or a combination thereof may be formed along sidewall surfaces of the openings 322, 324. In some examples, the TiSiN layer, if provided, may also be formed over the silicide layer 315. The layer of SiN, TiSiN, or the combination thereof, if formed, may have a thickness in a range of about 0.7-1.5 nm.

In a further embodiment of block 207, and after formation of the glue or barrier layer 326, a metal layer 328 may be formed over the device 300, including over the glue or barrier layer 326, both within each of the openings 322, 324 and outside the openings 322, 324. In some embodiments, prior to formation of the metal layer 328, the glue or barrier layer 326 may be treated to enhance adhesion and continuity of the subsequently formed metal layer 328, and to prevent interface roughness between the glue or barrier layer 326 and the subsequently formed metal layer 328. In various examples, the metal layer 328 may be deposited by CVD. However, in some cases, the metal layer 328 may be deposited by ALD, PVD, thermal evaporation, or other suitable technique. In accordance with embodiments of the present disclosure, the metal layer 328 may include Co, which will be subsequently annealed to optimize the grain size of the Co, as discussed herein. In some examples, the grain size of the as-deposited Co may be less than about 30 nm, which is sub-optimal for subsequent tungsten (W) via formation. In addition, it will be understood that, in some cases, other metals (e.g., such as Cu, Ru, Al, Rh, Mo, Ta, Ti, or other suitable conductive materials) may be used in combination with, or in place of, Co. In such examples, the subsequent annealing process may likewise be used to optimize the grain size of the respective metal, or combination thereof, that is used to form the metal layer 328.

The method 200 proceeds to block 208 where an annealing process is performed. With reference to FIGS. 5 and 6, and in an embodiment of block 208, an annealing process 317 may be performed to the metal layer 328 to form an annealed metal layer 328A and thereby modulate the grain size of the metal layer 328. Stated another way, the grain size of the annealed metal layer 328A will be larger than the grain size of the metal layer 328. In some embodiments, the annealing process 317 is performed at a temperature of about 250-400 degrees Celsius, in a 30-70% H₂ ambient environment (e.g., for improved impurity reduction), at a pressure of about 10-30 Torr, and for a duration of about 5-10 minutes. In some embodiments, a grain size of the annealed metal layer 328A (and thus the grain size of the subsequently formed contact plug), which may include an annealed Co layer, is in a range of about 30-90 nm². The grain size, as discussed herein, may in some cases correspond to an average grain size. In some examples, the average grain size of the annealed metal layer 328A may increase, as compared to the as-deposited metal layer 328, by a factor that is greater than one and less than or equal to three. By providing this optimized grain size, subsequent via formation (e.g., W via formation) on the Co contact plug will proceed at an ideal rate (e.g., about 8-12 Angstroms per second), as described below, thereby mitigating via-to-via variations and various other defects (e.g., such as Ti-insertion or a broken W layer). In various embodiments, and as a result of performing the annealing process 317, greater than 50% of the metal layer 328A (e.g., Co) may include a hexagonal close-packed (HCP) crystal structure. In other words, a majority of the metal layer 328 has an HCP crystal structure. In some embodiments, a ratio of a first portion of the metal layer 328A that has a HCP crystal structure to a second portion of the metal layer 328A that has a face-centered cubic (FCC) crystal structure is greater than about 1, and in some examples is in a range of between about 1-2. Because of the optimized Co grain size and corresponding crystal structure, a subsequently formed tungsten (W) via, as discussed below, may be formed in a controllable manner as low-resistivity alpha-tungsten (α-W). As a result, device performance will be improved.

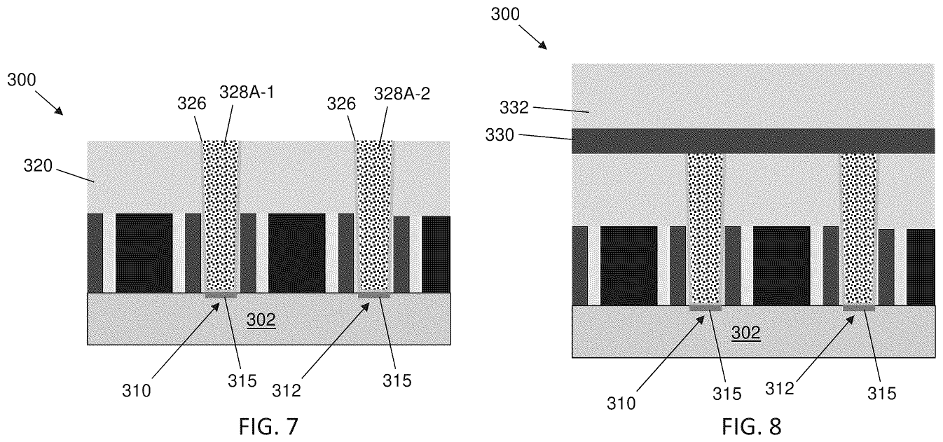

The method 200 proceeds to block 209 where a chemical mechanical polishing (CMP) process is performed. With reference to FIGS. 6 and 7, and in an embodiment of block 209, a CMP process is performed to remove excess material and planarize a top surface of the device 300. As shown, the CMP process may remove excess portions of the annealed metal layer 328A outside the openings 322, 324, thereby finalizing formation of a first contact plug 328A-1 and a second contact plug 328A-2, where the first contact plug 328A-1 contacts the region 310 and the second contact plug 328A-2 contacts the region 312. In some embodiments, the CMP process may also serve to remove excess portions of the glue or barrier layer 326 outside the openings 322, 324, thereby exposing a top surface of the dielectric layer 320. Thus, after the CMP process, top surfaces of the dielectric layer 320, the glue or barrier layer 326, the first contact plug 328A-1, and the second contact plug 328A-2 are substantially level (co-planar) with each other. It is noted that in some cases the first contact plug 328A-1 and the second contact plug 328A-2 may be equivalently referred to as metal plugs, plugs, or source/drain contacts.

The method 200 proceeds to block 210 where a contact etch stop layer and a second dielectric layer are deposited over the substrate. Referring to FIGS. 7 and 8, and in an embodiment of block 210, a contact etch stop layer (CESL) 330 is formed over the substrate 302, and a dielectric layer 332 is formed over the contact etch stop layer 330. By way of example, the contact etch stop layer 330 may include Ti, TiN, TiC, TiCN, Ta, TaN, TaC, TaCN, W, WN, WC, WCN, TiAl, TiAlN, TiAlC, TiAlCN, or combinations thereof. In some embodiments, the dielectric layer 332 may include an ILD layer that may include materials such as TEOS oxide, undoped silicate glass, or doped silicon oxide such as BPSG, FSG, PSG, BSG, and/or other suitable dielectric materials. Thus, in some cases, the dielectric layer 332 may be substantially the same as the dielectric layer 320. In various embodiments, the CESL 330 and the dielectric layer 332 may be deposited by a SACVD process, a flowable CVD process, an ALD process, a PVD process, or other suitable deposition technique.

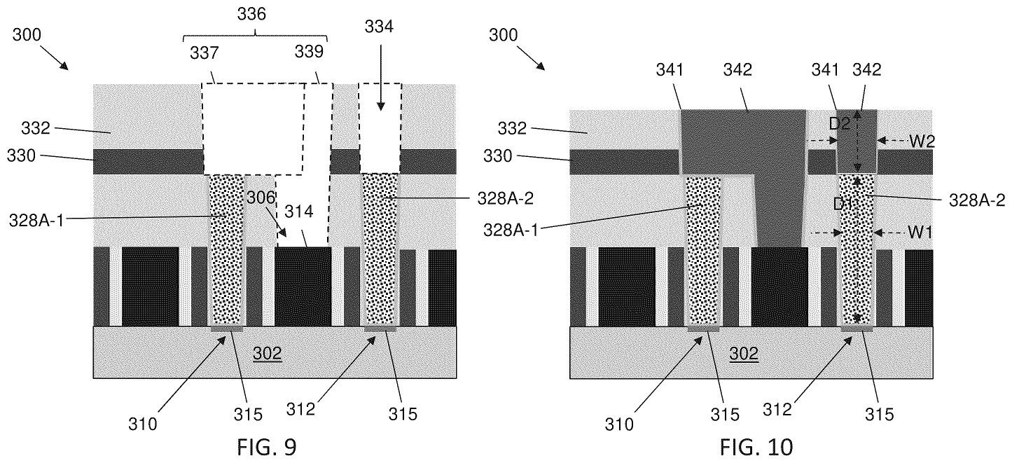

The method 200 proceeds to block 212 where via openings are formed. With reference to FIGS. 8 and 9, and in an embodiment of block 212, different examples of forming via openings are shown. In a first example, a contact via opening 334 is formed to provide access to the second contact plug 328A-2. The contact via opening 334 may be formed by a suitable combination of lithographic patterning and etching (e.g., wet or dry etching) processes. In some embodiments, one or more etching processes may be used to form the contact via opening 334, for example, to etch through each of the dielectric layer 332 and the CESL 330. In some embodiments, the contact via opening 334 may be substantially aligned (e.g., centered) with the second contact plug 328A-2 that is beneath the contact via opening 334. It will be understood that similar contact via openings may be formed to provide access to other contact plugs not explicitly shown.

In a second example, a composite via opening 336 may be formed, for instance, to provide for connection of the first contact plug 328A-1 to the gate electrode layer 314 of the gate structure 306. Initially, in some cases, a gate via opening 339 may be formed to provide access to the gate electrode layer 314 of the gate structure 306. The gate via opening 339 may be formed by a suitable combination of lithographic patterning and etching (e.g., wet or dry etching) processes. In some embodiments, one or more etching processes may be used to form the gate via opening 339, for example, to etch through each of the dielectric layer 332, the CESL 330, and the dielectric layer 320. In some embodiments, the gate via opening 339 may be substantially aligned (e.g., centered) with the gate electrode layer 314 of the gate structure 306 that is beneath the gate via opening 339. Thereafter, a contact via opening 337 may be formed to provide access to the first contact plug 328A-1. In some cases, the contact via opening 337 may be referred to as a slot via opening. The contact via opening 337 may be formed by a suitable combination of lithographic patterning and etching (e.g., wet or dry etching) processes. In some embodiments, one or more etching processes may be used to form the contact via opening 337, for example, to etch through each of the dielectric layer 332 and the CESL 330. Further, as illustrated in FIG. 9, the contact via opening 337 may merge/overlap with the gate via opening 339 to form the composite via opening 336. In some embodiments, the contact via opening 337 and the gate via opening 339 overlap each other by about 0-20 nm. After deposition of one or more metal layers, as described below, the composite via opening 336 will thus provide for contact between a metal gate layer and an adjacent source, drain, and/or body region. It will be understood that in the example described above, the contact via openings may be formed before the gate via openings, or the gate via openings may be formed before the contact via openings.

The method 200 proceeds to block 214 where metallization and chemical mechanical polishing processes are performed. With reference to FIGS. 9 and 10, and in an embodiment of block 214, a glue or barrier layer 341 may be formed within the contact via opening 334 and within the composite via opening 336. In some cases, the glue or barrier layer 341 may include Ti, TiN, Ta, TaN, a combination thereof, or other appropriate material. In at least some examples, the glue or barrier layer 341 includes a Ti/TiN stack. The glue or barrier layer 341, in some cases, may have a thickness in a range of about 0.5-1.5 nm. Additionally, and in an embodiment of block 214, a metal layer 342 may be formed on the glue or barrier layer 341 within the contact via opening 334 and within the composite via opening 336. In various examples, the metal layer 342 may be deposited by CVD. However, in some cases, the metal layer 342 may be deposited by ALD, PVD, thermal evaporation, or other suitable technique. In some examples, the deposition rate of the metal layer 342 may be in a range of about 8-12 Angstroms per second. In accordance with embodiments of the present disclosure, the metal layer 342 may include tungsten (W). However, in some cases, the metal layer 342 may include other metals (e.g., such as Cu, Co, Ru, Al, Rh, Mo, Ta, Ti, or other conductive materials) that may be used in combination with, or in place of, W. In embodiments when the metal layer 342 includes tungsten (W), and due to the optimized grain size of the underlying Co of the first contact plug 328A-1 and the second contact plug 328A-2, the metal layer 342 will form having a desirable, low-resistivity phase. In the present example, the metal layer 342 may thus form may form in the alpha phase as alpha-tungsten (α-W). Moreover, in some examples, the metal layer 342 may have a substantially uniform phase. It is noted that for the optimized grain size of the underlying Co (e.g., in a range of about 30-90 nm²), the tungsten (W) deposition rate (e.g., when the metal layer 342 includes tungsten (W)) may be in a range of about 8-12 Angstroms per second. Also, as previously mentioned, a topmost layer of the gate electrode layer 314 may include a tungsten (W) metal capping layer. Thus, in some cases, the portion of the metal layer 342 formed within the gate via opening 339 may also form over the tungsten (W) metal capping layer of the gate electrode layer 314. In particular, and in some embodiments, the portion of the metal layer 342 formed over the tungsten (W) metal capping layer of the gate electrode layer 314 may also include alpha-tungsten (α-W), as a bottom CD (e.g., of the gate via opening 339) may be greater than about 11 nm.

It is also generally noted that metal layer 342 within the composite via opening 336 may be equivalently described as the metal layer 342 formed within each of the contact via opening 337 and the gate via opening 339, where the contact via opening 337 and the gate via opening 339 merge/overlap, as described above. After deposition of the metal layer 342, and in an embodiment of block 214, a CMP process may be performed to remove excess material and planarize the top surface of the device 300. Thus, after deposition of the metal layer 342, contact is made to the second contact plug 328A-2, and contact is made between the first contact plug 328A-1 and the gate electrode layer 314 of the gate structure 306. FIG. 10 also illustrates a width and depth of a contact plug (e.g., such as the first contact plug 328A-1 or the second contact plug 328-2), denoted as W1 and D1, respectively. Further, FIG. 10 illustrates a width and depth of a via (e.g., such as the via formed in the contact via opening 334), denoted as W2 and D2, respectively. In some embodiments, W1 is in a range of between about 10-20 nm, and W2 is in a range of between about 11-17 nm. In some examples, D1 is in a range of between about 35-50 nm, and D2 is in a range of between about 15-35 nm.

The device 300 may undergo further processing to form various features and regions known in the art. For example, subsequent processing may form various contacts/vias/lines and multilayers interconnect features (e.g., metal layers and interlayer dielectrics) on the substrate 302, configured to connect the various features (e.g., including the contact via and the gate via) to form a functional circuit that may include one or more devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 200, and some process steps described above may be replaced or eliminated in accordance with various embodiments of the method 200.

As noted, the exemplary device 300 discussed above may include a planar device or a multi-gate device, such as the FinFET or a GAA device, among other device options. Regardless of the exact device type, embodiments of the present disclosure provide for forming a via, having an optimal and substantially uniform phase (e.g., such as alpha-tungsten), over an annealed contact plug having an optimal grain size (e.g., such as an annealed Co contact plug), where the grain size of the metal of the annealed contact plug is greater than the grain size of the as-deposited metal of the contact plug. With this in mind, it will be understood that embodiments of the present disclosure may be equally applied in other circumstances in which contact plugs and vias and formed.

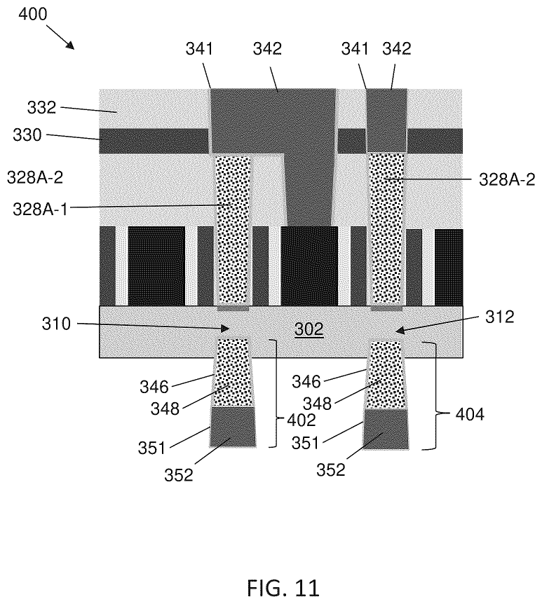

For example, with reference to FIG. 11, illustrated therein is a device 400, similar to the device 300, but further including backside contact structures 402, 404. In some embodiments, the backside contact structures 402, 404 may be similar to the contact plugs and contact vias described above, and they may be formed in a similar manner to that described with reference to the method 200, but the backside contact structures 402, 404 are formed along a backside surface of the substrate 302. For example, the backside contact structures 402, 404 may include glue or barrier layers 346 and 351, similar to the glue or barrier layers 326 and 341, discussed above. Further, the backside contact structures 402, 404 may include contact plugs 348, similar to the first and second contact plugs 328A-1 and 328A-2 discussed above, that are composed of annealed metal layers (e.g., annealed Co) having an optimized grain size and crystal structure. In addition, the backside contact structures 402, 404 may include metal layer 352 used to form vias, similar to the metal layer 342 discussed above, that may be composed of tungsten (W). Due to the optimized grain size of the contact plugs 348, the metal layer 352 (tungsten vias) will form having a desirable, low-resistivity phase. In the present example, the metal layer 352 may thus form may form in the alpha phase as alpha-tungsten (α-W). In some embodiments, the backside contact structures 402, 404 provide electrical contact to the regions 310, 312, where the regions 310, 312 may include a source/drain region or a body contact region, as previously discussed. Further, in some embodiments, a silicide layer (e.g., similar to the silicide layer 315) may be formed interposing the backside contact structures 402, 404 and the regions 310, 312. In some cases, the backside contact structures 402, 404 provide contact to a backside power delivery network.

The various embodiments described herein offer several advantages over the existing art. It will be understood that not all advantages have been necessarily discussed herein, no particular advantage is required for all embodiments, and other embodiments may offer different advantages. As one example, embodiments discussed herein include methods and structures directed to a fabrication process for contact structures and including contact plugs and contact vias. More particularly, embodiments of the present disclosure provide a method for optimizing the grain size of the Co used to form the contact plug, resulting in contacts and vias that are substantially defect-free, have reduced resistance, and provide improved gap-fill capability. In order to optimize the grain size of Co, various embodiments provide for optimizing the annealing process performed after Co deposition to modulate the grain size of the as-deposited Co. In some embodiments, the annealing process is performed at a temperature of about 250-400 degrees Celsius, in a 30-70% H₂ ambient environment (e.g., for improved impurity reduction), at a pressure of about 10-30 Torr, and for a duration of about 5-10 minutes. In some embodiments, a grain size of the annealed cobalt (and the subsequently formed Co contact plug) is in a range of about 30-90 nm². By providing this optimized Co grain size, the W via growth on the Co contact plug will proceed at an ideal rate (e.g., about 8-12 Angstroms per second) such that via-to-via variation and various other defects (e.g., such as Ti-insertion or a broken W layer) can be substantially avoided and device yield can be improved. Moreover, the optimized Co grain size provides for control of the W phase of the W vias (e.g., providing a substantially uniform film phase of the W vias), resulting in a boost in device performance. For instance, using the disclosed H₂ soak, greater than 50% of the Co may include a hexagonal close-packed (HCP) crystal structure, and the overlying W (used to form the W via) may form in the alpha phase as alpha-tungsten (α-W), which has a lower resistivity than beta-tungsten (β-W).

Thus, one of the embodiments of the present disclosure described a method including forming a first opening in a dielectric layer to expose a source/drain region. In some embodiments, the method further includes depositing a first metal layer in the opening and over the source/drain region. Thereafter, in some examples, the method further includes performing an annealing process to modulate a grain size of the first metal layer. In various embodiments, the method further includes depositing a second metal layer over the annealed first metal layer. In some embodiments, the second metal layer has a substantially uniform phase.

In another of the embodiments, discussed is a method including forming a first contact plug in contact with a first source/drain region and a second contact plug in contact with a second source/drain region. In some embodiments, the method further includes annealing the first and second contact plugs to increase a grain size of a first metal layer used to form each of the first and second contact plugs. In an example, the method further includes after annealing the first and second contact plugs, forming a first via over the first contact plug and a second via over the second contact plug. In some embodiments, a phase of a second metal layer used to form each of the first and second vias includes an alpha phase.

In yet another of the embodiments, discussed is a semiconductor device including a source/drain region. In some embodiments, the semiconductor device further includes a contact plug formed over the source/drain region, where the contact plug includes a cobalt (Co) layer, and where a majority of the Co layer has a hexagonal close-packed (HCP) crystal structure. In some examples, the semiconductor device further includes a via formed over the contact plug, where the via includes a tungsten (W) layer having a substantially uniform phase, the substantially uniform phase including an alpha phase.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first opening in a dielectric layer to expose a source/drain region;
depositing a first metal layer in the opening and over the source/drain region;
performing an annealing process to modulate a grain size of the first metal layer; and
depositing a second metal layer over the annealed first metal layer, wherein the second metal layer has a substantially uniform phase.

2. The method of claim 1, wherein the first metal layer defines a contact plug, and wherein the second metal layer defines a via.

3. The method of claim 1, wherein the first metal layer includes cobalt (Co), and wherein the second metal layer include tungsten (W).

4. The method of claim 1, wherein prior to performing the annealing process, the grain size of the first metal layer is less than about 30 nm.

5. The method of claim 1, wherein the annealed first metal layer has a grain size in a range of between about 30-90 nm².

6. The method of claim 1, wherein the second metal layer includes alpha-tungsten (α-W).

7. The method of claim 1, wherein the annealing process is performed at a temperature of between about 250-400 degrees Celsius, in a 30-70% H₂ ambient environment, at a pressure of between about 10-30 Torr, and for a duration of between about 5-10 minutes.

8. The method of claim 1, wherein the annealing process modulates the grain size of the first metal layer by a factor that is greater than one and less than or equal to three.

9. The method of claim 1, wherein greater than 50% of the annealed first metal layer has a hexagonal close-packed (HCP) crystal structure.

10. The method of claim 1, wherein a ratio of a first portion of the annealed first metal layer that has a hexagonal close-packed (HCP) crystal structure to a second portion of the annealed first metal layer that has a face-centered cubic (FCC) crystal structure is greater than about 1.

11. The method of claim 1, further comprising prior to depositing the first metal layer, forming a barrier layer in the opening, and depositing the first metal layer over the barrier layer.

12. A method, comprising:
forming a first contact plug in contact with a first source/drain region and a second contact plug in contact with a second source/drain region;
annealing the first and second contact plugs to increase a grain size of a first metal layer used to form each of the first and second contact plugs; and
after annealing the first and second contact plugs, forming a first via over the first contact plug and a second via over the second contact plug;
wherein a phase of a second metal layer used to form each of the first and second vias includes an alpha phase.

13. The method of claim 12, further comprising prior to forming the first and second contact plugs, forming a silicide layer over each of the first and second source/drain regions, and forming the first and second contact plugs over the silicide layer.

14. The method of claim 12, wherein the first source/drain region includes an N-type source/drain region, and wherein the second source/drain region includes a P-type source/drain region.

15. The method of claim 12, wherein at least one of the first and second vias includes a slot via merged with an adjacent gate via to provide a composite via, and wherein the composite via provides an electrical connection between the at least one of the first and second vias and a gate electrode layer of an adjacent gate structure.

16. The method of claim 12, wherein the first metal layer includes cobalt (Co), and wherein the second metal layer include tungsten (W).

17. The method of claim 12, wherein after annealing the first and second contact plugs, the grain size of the first metal layer is in a range of between about 30-90 nm².

18. The method of claim 12, wherein the annealing the first and second contact plugs is performed at a temperature of between about 250-400 degrees Celsius, in a 30-70% H₂ ambient environment, at a pressure of between about 10-30 Torr, and for a duration of between about 5-10 minutes.

19. A semiconductor device, comprising:
a source/drain region;
a contact plug formed over the source/drain region, wherein the contact plug includes a cobalt (Co) layer, and wherein a majority of the Co layer has a hexagonal close-packed (HCP) crystal structure; and
a via formed over the contact plug, wherein the via includes a tungsten (W) layer having a substantially uniform phase, the substantially uniform phase including an alpha phase.

20. The semiconductor device of claim 19, wherein a grain size of the Co layer is in a range of between about 30-90 nm².
